(19) United States
(12) Patent Application Publication
(10) Pub. No.: US 2023/0317503 A1
(43) Pub. Date: Oct. 5, 2023

(54) SUBSTRATE HOLDING HAND AND SUBSTRATE CONVEYING ROBOT

(71) Applicant: KAWASAKI JUKOGYO KABUSHIKI KAISHA, Kobe-shi, Hyogo (JP)

(72) Inventor: Ippei SHIMIZU, Kobe-shi (JP)

(73) Assignee: KAWASAKI JUKOGYO KABUSHIKI KAISHA, Kobe-shi, Hyogo (JP)

(21) Appl. No.: 18/024,616

(22) PCT Filed: Nov. 2, 2020
(86) PCT No.: PCT/JP2020/041031

§ 371 Date: Mar. 3, 2023

(30) Foreign Application Priority Data
Sep. 3, 2020 (JP) 2020-148495

(51) Int. Cl. H01L 21/687; B25J 11/00; B25J 15/00; H01L 21/67

(52) U.S. Cl. CPC H01L 21/68707; B25J 11/0095; B25J 15/0014; H01L 21/67259

(57) ABSTRACT

A substrate holding hand includes a sensor support member to support a plurality of substrate detection sensors and includes a positioner to collectively position the plurality of substrate detection sensors with respect to a plurality of blades.

### TECHNICAL FIELD

The present invention relates to a substrate holding hand and a substrate conveying robot, and more particularly, it relates to a substrate holding hand and a substrate conveying robot each including substrate detection sensors.

### BACKGROUND ART

Conventionally, a substrate conveying robot including a substrate conveying hand is known. Such a substrate conveying robot is disclosed in Japanese Patent Laid-Open No. 2013-069914, for example.

Japanese Patent Laid-Open No. 2013-069914 discloses a substrate conveying robot that is a horizontal articulated robot. This substrate conveying robot includes a base, an arm connected to the base and rotating in a horizontal plane, and substrate conveying hands connected to the arm and rotating in the horizontal plane. Each of the substrate conveying hands includes a hand main body (blade) that holds a substrate.

Although not clearly described in Japanese Patent Laid-Open No. 2013-069914, in a conventional substrate conveying robot as described in Japanese Patent Laid-Open No. 2013-069914, substrate detection sensors may be provided on substrate conveying hands to detect substrates held by the substrate conveying hands. The substrate detection sensors are positioned with respect to blades.

### PRIOR ART

### Patent Document

Patent Document 1: Japanese Patent Laid-Open No. 2013-069914

### SUMMARY OF THE INVENTION

### Problems to be Solved by the Invention

When a plurality of blades are provided and a plurality of substrate detection sensors are provided so as to correspond to the plurality of blades, it is necessary to position the plurality of substrate detection sensors with respect to the plurality of blades by the number of the plurality of substrate detection sensors. Therefore, the number of work processes to position the plurality of substrate detection sensors increases.

The present invention is intended to solve the above problems. The present invention aims to provide a substrate holding hand and a substrate conveying robot each capable of improving the workability of positioning substrate detection sensors.

### Means for Solving the Problems

A substrate holding hand according to a first aspect of the present invention includes a frame, a plurality of blades supported by the frame and to support substrates, a plurality of substrate detection sensors provided so as to correspond to the plurality of blades to detect a presence of the substrates, and a sensor support member to support the plurality of substrate detection sensors and including a positioner to collectively position the plurality of substrate detection sensors with respect to the plurality of blades.

As described above, the substrate holding hand according to the first aspect of the present invention includes the sensor support member to support the plurality of substrate detection sensors and including the positioner to collectively position the plurality of substrate detection sensors with respect to the plurality of blades. Accordingly, the plurality of substrate detection sensors are collectively positioned with respect to the plurality of blades by the sensor support member, and thus the number of work processes to position the plurality of substrate detection sensors can be reduced. Consequently, the work to position the substrate detection sensors can be simplified, and thus the workability of positioning the substrate detection sensors can be improved.

A substrate conveying robot according to a second aspect of the present invention includes a substrate holding hand and an arm to move the substrate holding hand. The substrate holding hand includes a frame, a plurality of blades supported by the frame and to support substrates, a plurality of substrate detection sensors provided so as to correspond to the plurality of blades to detect a presence of the substrates, and a sensor support member to support the plurality of substrate detection sensors and including a positioner to collectively position the plurality of substrate detection sensors with respect to the plurality of blades.

In the substrate conveying robot according to the second aspect of the present invention, as described above, the substrate holding hand includes the sensor support member to support the plurality of substrate detection sensors and including the positioner to collectively position the plurality of substrate detection sensors with respect to the plurality of blades. Accordingly, the plurality of substrate detection sensors are collectively positioned with respect to the plurality of blades by the sensor support member, and thus the number of work processes to position the plurality of substrate detection sensors can be reduced. Consequently, the work to position the substrate detection sensors can be simplified, and thus it is possible to provide the substrate conveying robot capable of improving the workability of positioning the substrate detection sensors.

### Effect of the Invention

According to the present invention, it is possible to improve the workability of positioning the substrate detection sensors.

### BRIEF DESCRIPTION OF THE DRAWINGS

FIG. 1 is a diagram showing the configuration of a substrate conveying robot according to an embodiment of the present invention.

FIG. 2 is a perspective view showing the configuration of a substrate holding hand according to the embodiment of the present invention.

FIG. 3 is a plan view showing the configuration of the substrate holding hand according to the embodiment of the present invention.

FIG. 4 is a perspective view showing the configuration of the substrate holding hand according to the embodiment of the present invention (a perspective view with a movable support unit and movable pressing units omitted).

FIG. 5 is a perspective view of a sensor support member according to the embodiment of the present invention, as viewed from above.

FIG. 6 is a plan view of the sensor support member according to the embodiment of the present invention.

FIG. 7 is a perspective view of the sensor support member according to the embodiment of the present invention, as viewed from below.

FIG. 8 is a side view of the sensor support member according to the embodiment of the invention.

### MODES FOR CARRYING OUT THE INVENTION

An embodiment embodying the present invention is hereinafter described on the basis of the drawings.

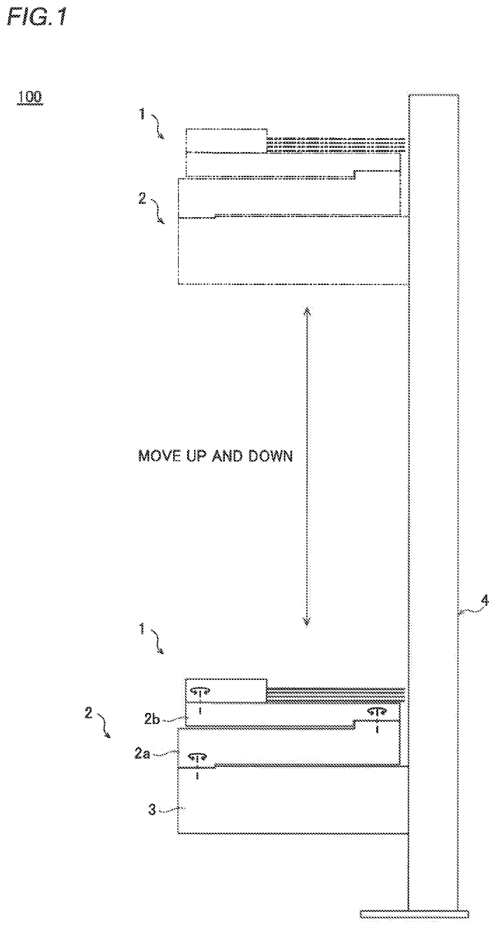

The configuration of a substrate conveying robot 100 according to this embodiment is now described with reference to FIGS. 1 to 8.

As shown in FIG. 1, the substrate conveying robot 100 includes a substrate holding hand 1 and an arm 2 that moves the substrate holding hand 1.

As shown in FIG. 1, the arm 2 is a horizontal articulated robot arm. The arm 2 includes a first arm 2a and a second arm 2b. The first arm 2a is rotatable with respect to a base 3, which is described below, with a first end as the center of rotation. Specifically, the first end of the first arm 2a is rotatably connected to the base 3 via a first joint. The second arm 2b is rotatable with respect to the first arm 2a with a first end as the center of rotation. Specifically, the first end of the second arm 2b is rotatably connected to a second end of the first arm 2a via a second joint. The substrate holding hand 1 is rotatably connected to a second end of the second arm 2b via a third joint. A drive mechanism including a servomotor corresponding to a drive source for rotary drive, a rotational position sensor that detects the rotational position of an output shaft of the servomotor, and a power transmission mechanism that transmits the output of the servomotor to the joint is provided at each of the first joint, the second joint, and the third joint.

The substrate conveying robot 100 further includes the base 3 to which the arm 2 is attached, and an arm elevating mechanism 4 to which the base 3 is attached. A first end of the base 3 is connected to the first end of the first arm 2a, and a second end of the base 3 is connected to the arm elevating mechanism 4. The arm elevating mechanism 4 moves the arm 2 up and down by moving the base 3 up and down.

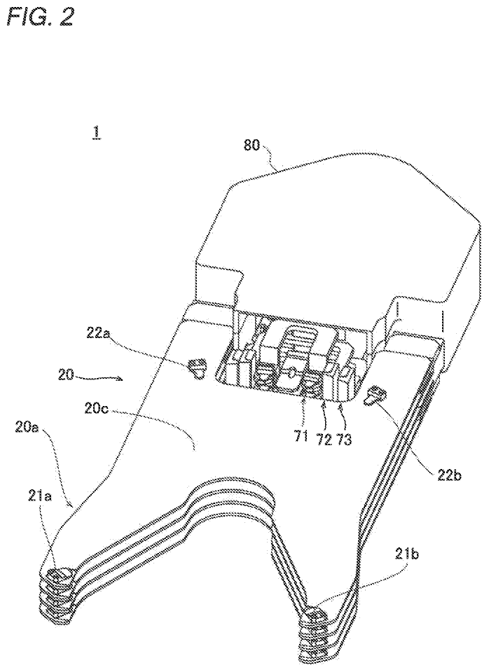

As shown in FIG. 2, the substrate holding hand 1 includes a plurality of (four) blades 20. That is, the substrate holding hand 1 can convey (hold) a plurality of (four) substrates W.

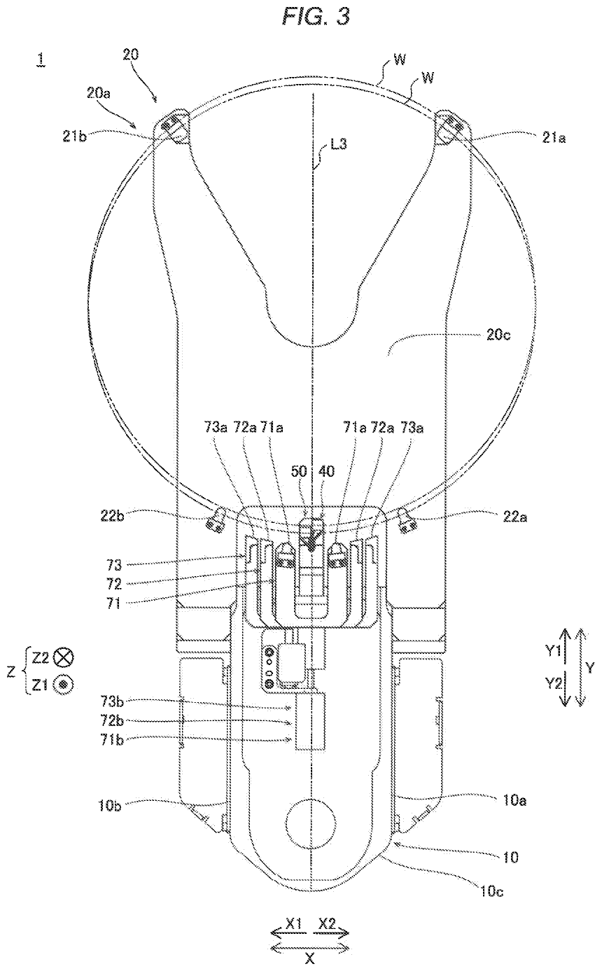

As shown in FIGS. 2 and 3, the substrate holding hand 1 includes a frame 10 and the blades 20. The frame 10 is a support that supports the blades 20. The frame 10 includes a pair of side walls 10a and 10b and a base end 10c connecting the pair of side walls 10a and 10b. The pair of side walls 10a and 10b are spaced apart from each other such that the wall surfaces thereof face each other in a direction (X direction) parallel to a direction in which a pair of front supports 21a and 21b are aligned. The pair of side walls 10a and 10b extend in a direction (Y direction) perpendicular to the direction in which the pair of front supports 21a and 21b are aligned and parallel to the main surfaces 20c of the blades 20. The base end 10c connects base ends (portions on the Y2 direction side) of the pair of side walls 10a and 10b. The base end 10c has a shape that is convexly curved toward the base end side (the Y2 direction side). The pair of side walls 10a and 10b and the base end 10c are provided in a U-shape, as viewed in a direction perpendicular to the main surfaces 20c of the blades 20.

The blades 20 are thin support plates that support the substrates W. Each of the blades 20 has a shape in which the tip end 20a side is bifurcated. In the blade 20, the pair of front supports 21a and 21b are distributed to the bifurcated portions. The pair of front supports 21a and 21b each have a plurality of (two) support surfaces at different heights. A pair of rear supports 22a and 22b each have a support surface at a height substantially the same as the heights of the lower (Z2 direction side) support surfaces of the pair of front supports 21a and 21b. The “height” refers to a distance from the main surfaces 20c of the blades 20 in the direction (Z direction) perpendicular to the main surfaces 20c of the blades 20.

The pair of front supports 21a and 21b and the pair of rear supports 22a and 22b are provided on the main surface 20c of each blade 20. The support surfaces of the pair of front supports 21a and 21b and the pair of rear supports 22a and 22b support the rear surface (the surface on the Z2 direction side) of the outer peripheral edge of a substantially circular substrate W from below.

In the direction (X direction) parallel to the direction in which the pair of front supports 21a and 21b are aligned, the pair of rear supports 22a and 22b are arranged inside (closer to a centerline L3 than) the pair of front supports 21a and 21b. Furthermore, in the direction (X direction) parallel to the direction in which the pair of front supports 21a and 21b are aligned, the pair of side walls 10a and 10b are arranged inside (closer to the centerline L3 than) the pair of rear supports 22a and 22b. The centerline L3 extends in the direction (Y direction) perpendicular to the direction in which the pair of front supports 21a and 21b are aligned and parallel to the main surfaces 20c of the blades 20.

The substrate holding hand 1 further includes a movable support unit 71 that moves back and forth to support the substrates W, and a first movable pressing unit 72 and a second movable pressing unit 73 that move back and forth to press the substrates W. The movable support unit 71 includes pairs of support members 71a that support the substrates W, and an air cylinder 71b corresponding to an actuator that moves the pairs of support members 71a back and forth in the Y direction. In the movable support unit 71, the pairs of support members 71a can be moved forward in a Y1 direction by the air cylinder 71b to be placed at support positions at which the pairs of support members 71a support the substrates W. Furthermore, in the movable support unit 71, the pairs of support members 71a can be moved backward in the Y2 direction by the air cylinder 71b to be placed at retracted positions at which the pairs of support members 71a do not support the substrates W. The pairs of support members 71a have support surfaces at heights substantially the same as the heights of the upper (Z1 direction side) support surfaces of the pairs of front supports 21a and 21b. Each support surface of the pairs of support members 71a supports the rear surface (the surface on the Z2 direction side) of the outer peripheral edge of the substantially circular substrate W from below. The first movable pressing unit 72 and the second movable pressing unit 73 are examples of a “movable pressing unit” in the claims.

The first movable pressing unit 72 includes a pair of pressing members 72a that press the substrates W, and an air cylinder 72b corresponding to an actuator that moves the pair of pressing members 72a back and forth in the Y direction. In the first movable pressing unit 72, the pair of pressing members 72a can be moved forward in the Y1 direction by the air cylinder 72b to press the substrates W. Furthermore, in the first movable pressing unit 72, the pair of pressing members 72a can be moved backward in the Y2 direction by the air cylinder 72b to be placed at retracted positions at which the pair of pressing members 72a do not press the substrates W.

The second movable pressing unit 73 includes a pair of pressing members 73a that press the substrates W, and an air cylinder 73b corresponding to an actuator that moves the pair of pressing members 73a back and forth in the Y direction. In the second movable pressing unit 73, the pair of pressing members 73a can be moved forward in the Y1 direction by the air cylinder 73b to press the substrates W. Furthermore, in the second movable pressing unit 73, the pair of pressing members 73a can be moved backward in the Y2 direction by the air cylinder 73b to be placed at retracted positions at which the pair of pressing members 73a do not press the substrates W.

In the substrate holding hand 1, the upper (Z1 direction side) support surfaces of the pairs of front supports 21a and 21b and the support surfaces of the pairs of support members 71a of the movable support unit 71 support the processed (washed) substrates W. The pair of pressing members 72a of the first movable pressing unit 72 press the processed (washed) substrates W supported by the upper (Z1 direction side) support surfaces of the pairs of front supports 21a and 21b and the support surfaces of the pairs of support members 71a of the movable support unit 71.

In the substrate holding hand 1, the lower (Z2 direction side) support surfaces of the pairs of front supports 21a and 21b and the support surfaces of the pairs of rear supports 22a and 22b support the substrates W prior to processing (washing). The pair of pressing members 73a of the second movable pressing unit 73 press the substrates W prior to processing (washing) supported by the lower (Z2 direction side) support surfaces of the pairs of front supports 21a and 21b and the support surfaces of the pairs of rear supports 22a and 22b. The pairs of front supports 21a and 21b, the pairs of rear supports 22a and 22b, the movable support unit 71, the first movable pressing unit 72, and the second movable pressing unit 73 are used properly for the substrates W prior to processing (washing) and the processed (washed) substrates W.

The air cylinder 71b of the movable support unit 71, the air cylinder 72b of the first movable pressing unit 72, and the air cylinder 73b of the second movable pressing unit 73 are arranged on the inside of the frame 10. The air cylinder 71b of the movable support unit 71, the air cylinder 72b of the first movable pressing unit 72, and the air cylinder 73b of the second movable pressing unit 73 are aligned in the direction (Z direction) perpendicular to the main surfaces 20c of the blades 20 on the inside of the frame 10. Specifically, the air cylinder 71b of the movable support unit 71, the air cylinder 72b of the first movable pressing unit 72, and the air cylinder 73b of the second movable pressing unit 73 overlap each other, as viewed in the direction (Z direction) perpendicular to the main surfaces 20c of the blades 20. Therefore, the air cylinders 71b, 72b, and 73b are not aligned in the width direction (X direction) of the frame 10, and thus the air cylinders 71b, 72b, and 73b can be compactly arranged in the width direction (X direction) of the frame 10.

The substrate holding hand 1 further includes a cover (casing) 80 (see FIG. 2) separately from the frame 10. The cover 80 covers the frame 10 and portions (portions arranged on the inside of the frame 10) of the movable support unit 71, the first movable pressing unit 72, and the second movable pressing unit 73.

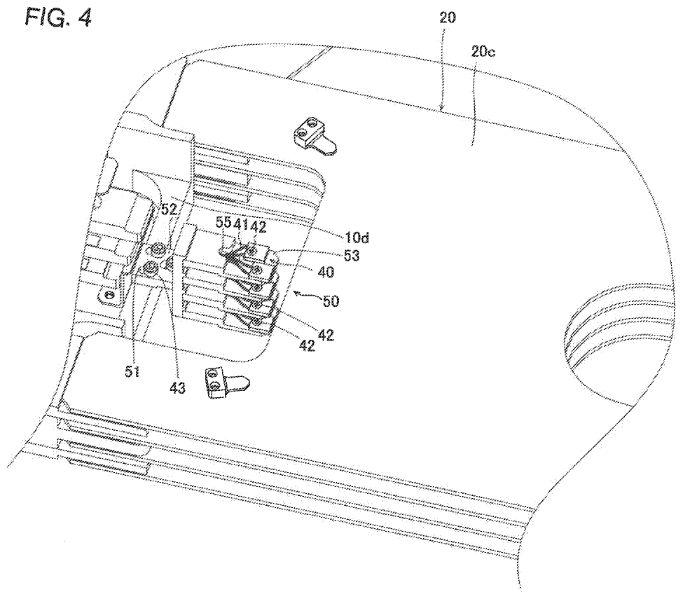

As shown in FIG. 4, the substrate conveying robot 100 includes a plurality of substrate detection sensors 40 provided so as to correspond to the plurality of blades 20, each of which supports the substrate (semiconductor wafer) W, to detect the presence of the substrates W, and a sensor support member 50 that supports the plurality of substrate detection sensors 40 and includes first holes 51 to collectively position the plurality of substrate detection sensors 40 with respect to the plurality of blades 20. The first holes 51 are examples of a “positioner” in the claims. In FIG. 4, the movable support unit 71, the first movable pressing unit 72, and the second movable pressing unit 73 are omitted.

The substrate detection sensors 40 are any one of (reflective or transmissive) optical sensors, capacitance sensors, distance sensors, and touch sensors (sensors designed on the assumption that they contact the substrates W). In this embodiment, the substrate detection sensors 40 are reflective optical sensors. In the case of optical sensors, it is necessary to finely adjust the inclinations, and thus the sensor support member 50 according to this embodiment, which collectively positions the plurality of substrate detection sensors 40 with respect to the plurality of blades 20, is particularly effective.

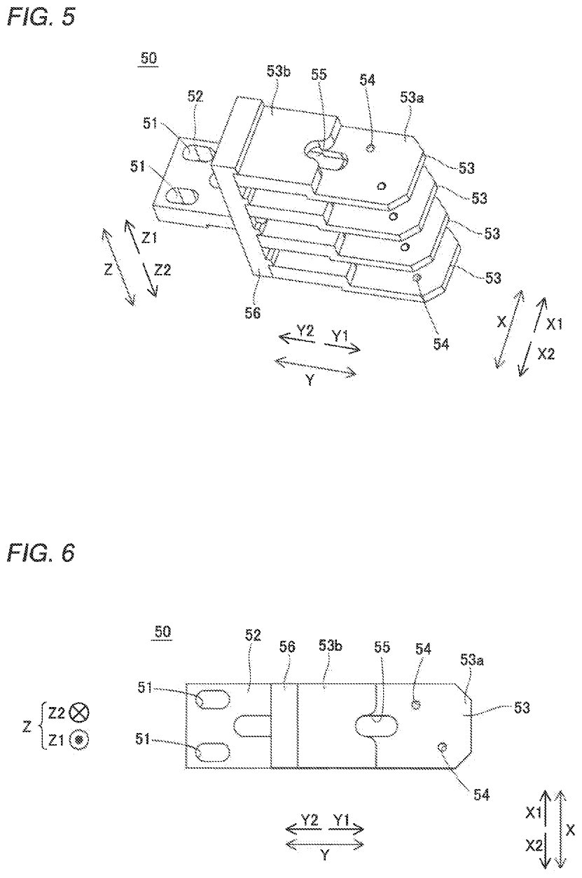

In this embodiment, as shown in FIGS. 5 and 6, the sensor support member 50 is provided in common for the plurality of substrate detection sensors 40, and further includes a fixing portion 52 to fix the sensor support member 50 to the frame 10. The first holes 51 are provided in the fixing portion 52. The fixing portion 52 has a plate shape extending along the Y direction.

In this embodiment, the first holes 51 allow the position of the fixing portion 52 to be adjusted along a direction (Y1 direction) toward the blades 20. That is, the fixing portion 52 is slidable along the Y direction with respect to screws 43 (see FIG. 4) inserted into the fixing portion 52.

In this embodiment, the first holes 51 each have an elongated hole shape (oval shape) extending along the direction (Y1 direction) toward the blades 20.

In this embodiment, a plurality of first holes 51 each having an elongated hole shape are provided in the fixing portion 52. Specifically, two first holes 51 are provided in the fixing portion 52. The two first holes 51 are arranged adjacent to each other along the X direction.

In this embodiment, the plurality of substrate detection sensors 40 are positioned with respect to the plurality of blades 20 by fixing the fixing portion 52 to the frame 10. Specifically, the screw 43 is inserted into each of the two first holes 51. In this state, the position of the fixing portion 52 (substrate detection sensors 40) in the Y direction is adjusted. The sensor support member 50 is fixed to the frame 10 by fastening the screws 43 to the tip end 10d (see FIG. 4) of the frame 10. Thus, the plurality of substrate detection sensors 40 are positioned with respect to the plurality of blades 20.

In this embodiment, the plurality of blades 20 provided on the substrate holding hand 1 are arranged in a stacked manner along a vertical direction (Z direction) perpendicular to the main surfaces 20c of the blades 20, and the sensor support member 50 includes a plurality of plate-shaped sensor placement portions 53 stacked along the vertical direction so as to correspond to the plurality of blades 20 stacked along the vertical direction. The term “stack” also includes the concept of being stacked while being spaced apart from each other.

Specifically, four blades 20 are provided on the substrate holding hand 1. Four plate-shaped sensor placement portions 53 are provided so as to correspond to the four blades 20. The sensor placement portions 53 each have a stepped shape. The substrate detection sensors 40 are arranged on lower steps 53a of the sensor placement portions 53 each having a stepped shape. The corners of the sensor placement portions 53 on the Y1 direction side are chamfered.

The sensor support member 50 also includes a connecting member 56 having a Y1 direction side to which the four sensor placement portions 53 are connected and a Y2 direction side to which the fixing portion 52 is connected. The connecting member 56 has a plate shape. The connecting member 56 is provided along the Z direction.

In this embodiment, each of the plurality of sensor placement portions 53 includes second holes 54 for fastening and fixing the substrate detection sensors 40 with screws 42 (see FIG. 4). The second holes 54 are provided in the lower steps 53a of the sensor placement portions 53 each having a stepped shape.

In this embodiment, each of the plurality of plate-shaped sensor placement portions 53 includes a third hole 55 through which wiring 41 (see FIG. 4) extending from the substrate detection sensors 40 is inserted. The third hole 55 is provided at a boundary between the lower step 53a and an upper step 53b of the sensor placement portion 53 having a stepped shape.

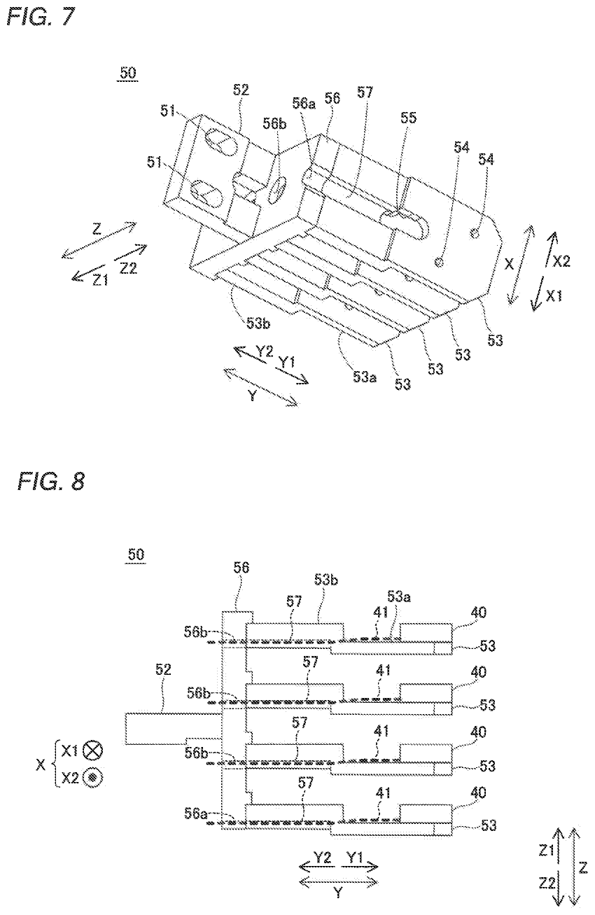

In this embodiment, as shown in FIG. 7, each of the plurality of plate-shaped sensor placement portions 53 includes a guide groove 57 that guides the wiring 41 inserted from the third hole 55. The guide groove 57 extends from the Y1 direction side to the Y2 direction side on the Z2 direction side of the upper step 53b. The wiring 41 is arranged inside the guide groove 57. The wiring 41 guided by the guide groove 57 is guided to the Y2 direction side of the connecting member 56 via a notch 56a or a hole 56b provided in the connecting member 56. As shown in FIG. 8, the guide groove 57 is provided such that it is possible to reduce the degree of bending of the wiring 41 extending in the Y2 direction from the substrate detection sensor 40 (to make the wiring closer to a straight line).

In this embodiment, as shown in FIG. 3, the movable support unit 71 that moves back and forth to support the substrates W has a U-shape, as viewed in the Z direction. Furthermore, each of the first movable pressing unit 72 and the second movable pressing unit 73 that move back and forth to press the substrates W has a U-shape, as viewed in the Z direction. The substrate detection sensors 40 and the sensor support member 50 are arranged inside the U-shaped movable support unit 71 and the U-shaped first movable pressing unit 72 and second movable pressing unit 73. Specifically, the substrate detection sensors 40 and the sensor support member 50 are interposed between U-shaped portions of the U-shaped movable support unit 71.

Specifically, the U-shaped first movable pressing unit 72 is arranged inside the U-shaped second movable pressing unit 73, as viewed in the Z direction. The U-shaped movable support unit 71 is arranged inside the U-shaped first movable pressing unit 72, as viewed in the Z direction. The substrate detection sensors 40 and the sensor support member 50 are arranged inside the U-shaped movable support unit 71, as viewed in the Z direction.

### Advantages of this Embodiment

According to this embodiment, the following advantages are achieved.

According to this embodiment, as described above, the substrate holding hand 1 includes the sensor support member 50 that supports the plurality of substrate detection sensors 40 and includes the first holes 51 to collectively position the plurality of substrate detection sensors 40 with respect to the plurality of blades 20. Accordingly, the plurality of substrate detection sensors 40 are collectively positioned with respect to the plurality of blades 20 by the sensor support member 50, and thus the number of work processes to position the plurality of substrate detection sensors 40 can be reduced. Consequently, the work to position the substrate detection sensors 40 can be simplified, and thus the workability of positioning the substrate detection sensors 40 can be improved.

According to this embodiment, as described above, the sensor support member 50 is provided in common for the plurality of substrate detection sensors 40, and further includes the fixing portion 52 to fix the sensor support member 50. The first holes 51 are provided in the fixing portion 52. Accordingly, the fixing portion 52 is provided in common for the plurality of substrate detection sensors 40, and thus the plurality of substrate detection sensors 40 can be collectively positioned easily by the first holes 51 provided in the common fixing portion 52.

According to this embodiment, as described above, the first holes 51 are operable to allow the position of the fixing portion 52 to be adjusted along the direction toward the blades 20. Accordingly, even when a distance between the first holes 51 and the blade 20 varies due to manufacturing errors, for example, the distance to the blade 20 can be adjusted by the first holes 51.

According to this embodiment, as described above, the first holes 51 each have an elongated hole shape extending along the direction toward the blades 20. Accordingly, the fixing portion 52 can be slid along the direction toward the blades 20 with respect to the screws 43 or the like inserted into the elongated first holes 51. Consequently, the position of the fixing portion 52 can be easily adjusted along the direction toward the blades 20. Furthermore, the elongated first holes 51 allow the fixing portion 52 to move only in the direction toward the blades 20, and thus the fixing portion 52 can be positioned in a direction perpendicular to the direction toward the blades 20.

According to this embodiment, as described above, the plurality of first holes 51 each having an elongated hole shape are provided in the fixing portion 52. Accordingly, the screws 43 or the like are inserted into the plurality of first holes 51, and thus unlike a case in which only one first hole 51 having an elongated hole shape is provided, rotation of the fixing portion 52 within a horizontal plane including the direction toward the blades 20 can be reduced or prevented.

According to this embodiment, as described above, the plurality of substrate detection sensors 40 are positioned with respect to the plurality of blades 20 by fixing the fixing portion 52 to the frame 10. Accordingly, the fixing portion 52 (sensor support member 50) is fixed to the frame 10 that supports the plurality of blades 20, and thus a deviation in the relative positional relationship between the plurality of substrate detection sensors 40 supported by the sensor support member 50 and the plurality of blades 20 can be reduced or prevented.

According to this embodiment, as described above, the plurality of blades 20 are arranged in a stacked manner along the vertical direction perpendicular to the main surfaces 20c of the blades 20, and the sensor support member 50 includes the plurality of plate-shaped sensor placement portions 53 stacked along the vertical direction so as to correspond to the plurality of blades 20 stacked along the vertical direction. Accordingly, the plurality of substrate detection sensors 40 can be easily arranged so as to correspond to the plurality of stacked blades 20.

According to this embodiment, as described above, each of the plurality of sensor placement portions 53 includes the second holes 54 to allow the substrate detection sensor 40 to be fastened and fixed. Accordingly, the plurality of substrate detection sensors 40 can be easily fixed to the plurality of sensor placement portions 53 by fastening the substrate detection sensors 40 to the sensor placement portions 53 with the screws 43 through the second holes 54.

According to this embodiment, as described above, each of the plurality of plate-shaped sensor placement portions 53 includes the third hole 55 to allow the wiring 41 extending from the substrate detection sensor 40 to be inserted therethrough. Accordingly, the wiring 41 extending from the substrate detection sensor 40 can be guided to a desired position (such as a space inside the substrate holding hand 1) through the third hole 55. Furthermore, movement of the wiring 41 extending from the substrate detection sensor 40 is restricted by the third hole 55, and thus contact of the wiring 41 with another member due to movement of the substrate holding hand 1 can be reduced or prevented.

According to this embodiment, each of the plurality of plate-shaped sensor placement portions 53 includes the guide groove 57 to guide the wiring 41 inserted from the third hole 55. Accordingly, the wiring 41 can be arranged inside the guide groove 57, and thus interference between the wiring 41 and another member can be reduced or prevented.

According to this embodiment, as described above, the substrate holding hand 1 further includes the U-shaped movable support unit 71 that moves back and forth to support the substrates W and the U-shaped first and second movable pressing units 72 and 73 that move back and forth to press the substrates W, and the substrate detection sensors 40 and the sensor support member 50 are arranged inside the U-shaped movable support unit 71 and the U-shaped first and second movable pressing units 72 and 73. Accordingly, the substrate detection sensors 40 and the sensor support member 50 are arranged in an empty space inside the U-shaped movable support unit 71 and the U-shaped first and second movable pressing units 72 and 73, and thus the empty space can be effectively used (that is, an increase in the size of the substrate holding hand 1 can be reduced or prevented).

### Modified Examples

The embodiment disclosed this time must be considered as illustrative in all points and not restrictive. The scope of the present invention is not shown by the above description of the embodiment but by the scope of claims for patent, and all modifications (modified examples) within the meaning and scope equivalent to the scope of claims for patent are further included.

For example, while the example in which the first holes 51 allow the position of the fixing portion 52 to be adjusted along the direction toward the blades 20 has been shown in the aforementioned embodiment, the present invention is not limited to this. For example, the first holes 51 may not allow the position to be adjusted along the direction toward the blades 20. That is, the first holes 51 may be perfectly circular. Alternatively, the first holes 51 may have a cross shape to allow the position to be adjusted both in the direction toward the blades 20 and in the direction perpendicular to this direction.

While the example in which a plurality of first holes 51 are provided in the fixing portion 52 has been shown in the aforementioned embodiment, the present invention is not limited to this. For example, only one first hole 51 may be provided in the fixing portion 52.

While the example in which the first holes 51 are applied as the “positioner” according to the present invention has been shown in the aforementioned embodiment, the present invention is not limited to this. Configurations other than the first holes 51 may be applied as the “positioner” according to the present invention.

While the example in which the fixing portion 52 is fixed to the frame 10 has been shown in the aforementioned embodiment, the present invention is not limited to this. For example, the fixing portion 52 may be fixed to a portion of the substrate holding hand 1 other than the frame 10.

While the example in which four blades 20 are provided has been shown in the aforementioned embodiment, the present invention is not limited to this. For example, the number of blades 20 may be plural other than four.

While the example in which the substrate detection sensors 40 and the sensor support member 50 are arranged inside the U-shaped movable support unit 71 and the U-shaped first and second movable pressing units 72 and 73 has been shown in the aforementioned embodiment, the present invention is not limited to this. For example, the substrate detection sensors 40 and the sensor support member 50 may be arranged outside the movable support unit 71, the first movable pressing unit 72, and the second movable pressing unit 73.

### DESCRIPTION OF REFERENCE NUMERALS

1: substrate holding hand
2: arm
10: frame
20: blade
20c: main surface
40: substrate detection sensor
41: wiring
50: sensor support member
51: first hole (positioner)
52: fixing portion
53: sensor placement portion
54: second hole
55: third hole
57: guide groove
71: movable support unit
72: first movable pressing unit (movable pressing unit)
73: second movable pressing unit (movable pressing unit)
100: substrate conveying robot
W: substrate

1. A substrate holding hand comprising:
a frame;
a plurality of blades supported by the frame and to support substrates;
a plurality of substrate detection sensors provided so as to correspond to the plurality of blades to detect a presence of the substrates; and
a sensor support member to support the plurality of substrate detection sensors, the sensor support member including a positioner to collectively position the plurality of substrate detection sensors with respect to the plurality of blades.

2. The substrate holding hand according to claim 1, wherein
the sensor support member is provided in common for the plurality of substrate detection sensors, and further includes a fixing portion to fix the sensor support member; and
the positioner is provided in the fixing portion.

3. The substrate holding hand according to claim 2, wherein the positioner is operable to allow a position of the fixing portion to be adjusted along a direction toward the blades.

4. The substrate holding hand according to claim 3, wherein the positioner includes an elongated first hole extending along the direction toward the blades.

5. The substrate holding hand according to claim 4, wherein the elongated first hole includes a plurality of elongated first holes provided in the fixing portion.

6. The substrate holding hand according to claim 2, wherein the plurality of substrate detection sensors are positioned with respect to the plurality of blades by fixing the fixing portion to the frame.

7. The substrate holding hand according to claim 1, wherein
the plurality of blades are arranged in a stacked manner along a vertical direction perpendicular to main surfaces of the blades; and
the sensor support member includes a plurality of plate-shaped sensor placement portions stacked along the vertical direction so as to correspond to the plurality of blades stacked along the vertical direction.

8. The substrate holding hand according to claim 7, wherein each of the plurality of sensor placement portions includes a second hole to allow each of the substrate detection sensors to be fastened and fixed.

9. The substrate holding hand according to claim 7, wherein each of the plurality of plate-shaped sensor placement portions includes a third hole to allow wiring extending from each of the substrate detection sensors to be inserted therethrough.

10. The substrate holding hand according to claim 9, wherein each of the plurality of plate-shaped sensor placement portions includes a guide groove to guide the wiring inserted from the third hole.

11. The substrate holding hand according to claim 1, further comprising:
a U-shaped movable support unit that moves back and forth to support the substrates; and
a U-shaped movable pressing unit that moves back and forth to press the substrates; wherein
the substrate detection sensors and the sensor support member are arranged inside the U-shaped movable support unit and the U-shaped movable pressing unit.

12. A substrate conveying robot comprising:
a substrate holding hand; and
an arm to move the substrate holding hand; wherein
the substrate holding hand includes:
a frame;
a plurality of blades supported by the frame and to support substrates;
a plurality of substrate detection sensors provided so as to correspond to the plurality of blades to detect a presence of the substrates; and
a sensor support member to support the plurality of substrate detection sensors, the sensor support member including a positioner to collectively position the plurality of substrate detection sensors with respect to the plurality of blades.
